(19) United States
(12) Patent Application Publication
(10) Pub. No.: US 2026/0096224 A1
(43) Pub. Date: Apr. 2, 2026

(54) HIGH VOLTAGE POWER DEVICE WITH ELECTROSTATIC DISCHARGE SELF-PROTECTION STRUCTURE

(71) Applicant: SK keyfoundry Inc., Cheongju-si (KR)

(72) Inventor: Youngbae KIM, Sejong-si (KR)

(73) Assignee: SK keyfoundry Inc., Cheongju-si (KR)

(21) Appl. No.: 19/053,052

(22) Filed: Feb. 13, 2025

(30) Foreign Application Priority Data
Sep. 30, 2024 (KR) 10-2024-0132423

(51) Int. Cl. H10D 89/60; H10D 8/60; H10D 62/10; H10D 64/00

(52) U.S. Cl. CPC H10D 89/713; H10D 8/60; H10D 62/106; H10D 64/111; H10D 89/611; H10D 89/811

(57) ABSTRACT

A semiconductor device includes a high voltage region formed on a semiconductor substrate; a junction isolation region surrounding the high voltage region; a Schottky diode configured to supply a forward current to the high voltage region; a silicon controlled rectifier (SCR) region formed between the Schottky diode and the high voltage region; a drain region, a gate region and a source region formed in the SCR region; a P-type isolation region formed between the Schottky diode and the source region; a first SCR including a first N+ region and a first P+ region in contact with each other and formed in the drain region; a second SCR comprising a second N+ region and a second P+ region in contact with each other and formed in the gate region; and a third SCR comprising a third N+ region and a third P+ region in contact with each other and formed in the P-type isolation region.

### CROSS REFERENCE TO RELATED APPLICATION

This application claims the benefit under 35 U.S.C. 119 (a) of Korean Patent Application No. 10-2024-0132423, filed on Sep. 30, 2024, in the Korean Intellectual Property Office, the entire disclosure of which is incorporated herein by reference for all purposes.

### BACKGROUND

### 1. Field

The following description relates to a high voltage power device with electrostatic discharge (ESD) self-protection structure.

### 2. Discussion of Related Art

The statements in this section merely provide background information related to the present disclosure and do not necessarily constitute prior art.

High voltage (HV) semiconductor devices over 600V, comprising a high side gate driver IC and a low side gate driver IC, are widely used in motor drivers. HV semiconductor devices use bootstrap diodes and level shifters to operate at high voltages on the order of 600V or 1200V to drive power MOSFETs or discrete devices. While the HV semiconductor device is operating, high ESD currents can flow through several components of the HV semiconductor device, such as the bootstrap diode, level shifter, high side gate driver IC, and low side gate driver IC. Several ESD structures have been proposed to block the high ESD currents flowing in these components. However, these ESD structures may require a large chip area. To reduce the large chip area, HV semiconductor devices with ESD self-protection structure may be required.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a semiconductor device includes a high voltage region formed on a semiconductor substrate; a junction isolation region surrounding the high voltage region; a Schottky diode configured to supply a forward current to the high voltage region; a silicon controlled rectifier (SCR) region formed between the Schottky diode and the high voltage region; a drain region, a gate region and a source region formed in the SCR region; a P-type isolation region formed between the Schottky diode and the source region; a first SCR including a first N+ region and a first P+ region in contact with each other and formed in the drain region; a second SCR including a second N+ region and a second P+ region in contact with each other and formed in the gate region; and a third SCR including a third N+ region and a third P+ region in contact with each other and formed in the P-type isolation region.

The semiconductor device may further include an NP guard ring and a PNP guard ring that surround the Schottky diode. The NP guard ring may include a fourth N+ region formed on a first N-type buried layer (NBL); and a fourth P+ region formed on a first P-type buried layer (PBL). The PNP guard ring may include a fifth P+ region formed on a second PBL; a fifth N+ region formed on a second NBL; and a sixth P+ region formed on a third PBL. A fourth SCR may include the fourth N+ region and the fourth P+ region.

The drain region may include a drain N-type well region (NW) surrounding the first SCR; and a field plate electrically connected to the first SCR and formed on a field oxide layer. The gate region may include an N-type deep well region (DNW) formed on the semiconductor substrate; a P-type top layer (PTOP) formed on the DNW; a P-type body region (PBODY) connected to the PTOP; the second SCR formed on the PBODY; and a gate electrode formed to overlap the PBODY. The source region may include an N+ source region formed on the DNW.

The P-type isolation may include a P-type isolation buried layer (ISO PBL) formed under the third SCR.

The first SCR is connected to a high voltage terminal, and the second SCR, the third SCR, and the fourth SCR may be connected to a ground voltage.

The Schottky diode may include a third NBL formed in the semiconductor substrate; an N-type deep well region (DNW) formed on the third NBL; an N-type cathode well region formed on the DNW; a P-type anode well region formed separately from the N-type cathode well region by a separator; a first silicide formed on the N-type cathode well region; a second silicide formed on the P-type anode well region; a cathode electrode formed on the first silicide; and an anode electrode formed on the second silicide. The cathode electrode may be electrically connected to a source electrode of the source region.

In another general aspect, a semiconductor device includes a high voltage region formed on a semiconductor substrate; a junction isolation region surrounding the high voltage region; a Schottky diode configured to supply a forward current to the high voltage region; a silicon controlled rectifier (SCR) region formed between the Schottky diode and the high voltage region; and a drain region, a gate region and a source region formed in the SCR region. The SCR region may include a first SCR comprising a first N+ region and a first P+ region in contact with each other and formed on a drain N-type well region (NW); a second SCR comprising a second N+ region and a second P+ region in contact with each other and formed on a P-type body region (PBODY); and a third SCR comprising a third N+ region and a third P+ region in contact with each other and formed on a P-type isolation region.

The semiconductor device may further include an NP guard ring and a PNP guard ring that surround the Schottky diode. The NP guard ring may include a fourth N+ region formed on a first N-type buried layer (NBL); and a fourth P+ region formed on a first P-type buried layer (PBL). The PNP guard ring may include a fifth P+ region formed on the second PBL; a fifth N+ region formed on a second NBL; and a sixth P+ region formed on a third PBL. A fourth SCR may include the fourth N+ region and the fourth P+ region.

The drain region including the first SCR may further include a field plate electrically connected to the first SCR and formed on a field oxide layer, and the gate region including the second SCR may further include a P-type top layer (PTOP) connected to the PBODY; and a gate electrode formed on the PBODY.

The P-type isolation region including the third SCR may further include a P-type isolation buried layer formed under the third SCR.

The first SCR may be connected to a high voltage terminal, and the second SCR, the third SCR, and the fourth SCR may be connected to a ground voltage.

The Schottky diode may include a third NBL formed in the semiconductor substrate; an N-type deep well region (DNW) formed on the third NBL; an N-type cathode well region formed on the DNW; a P-type anode well region formed separately from the N-type cathode well region by a separator; a first silicide formed on the N-type cathode well region; a second silicide formed on the P-type anode well region; a cathode electrode formed on the first silicide; and an anode electrode formed on the second silicide.

The source region may be formed between the second SCR and the third SCR. The source region may include an N+ source region formed on the DNW and a source electrode connected to the source region. The source electrode may be electrically connected to the cathode electrode.

According to one embodiment of the present disclosure, when ESD is applied through a terminal for connection to the outside, damage to internal components due to ESD may be prevented by using the SCR that can quickly release the voltage.

Other features and aspects will be apparent from the following detailed description, the drawings, and the claims.

### BRIEF DESCRIPTION OF THE DRAWINGS

FIG. 1 illustrates a circuit view of a high voltage integrated circuit according to one embodiment of the present disclosure;

FIG. 2 illustrates a plan view of a high voltage power device comprising a Schottky diode with ESD self-protection structure according to one embodiment of the present disclosure;

FIG. 3 illustrates a cross-sectional view of a high voltage power device comprising a Schottky diode with ESD self-protection structure according to one embodiment of the present disclosure;

FIG. 4 illustrates a cross-sectional view of a high voltage power device comprising a Schottky diode with ESD self-protection structure according to one embodiment of the present disclosure;

FIGS. 5 to 7 illustrate cross-sectional views showing an ESD current discharge path according to one or more embodiments of the present disclosure.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness, noting that omissions of features and their descriptions are also not intended to be admissions of their general knowledge.

The use of the term “may” herein with respect to an example or embodiment, e.g., as to what an example or embodiment may include or implement, means that at least one example or embodiment exists where such a feature is included or implemented, while all examples are not limited thereto.

Hereinafter, a display device according to embodiments of the present disclosure will be described, referring to the accompanying drawings. It will be understood that when an element is referred to as being “connected with”, “on” or “coupled to” another element, the element can be directly connected with the other element or intervening elements may also be present. In contrast, when an element is referred to as being “directly connected with” another element, there are no intervening elements present.

Throughout the disclosure, each component can be provided as a single one or a plurality of ones, unless explicitly stated to the contrary. Terms such as “comprise” or “has” are used herein and should be understood that they are intended to indicate an existence of several components, functions or steps, disclosed in the specification, and it is also understood that greater or fewer components, functions, or steps may likewise be utilized.

It will be understood that the terms “first” and “second” are used herein to describe various components but these components should not be limited by these terms. The above terms are used only to distinguish one component from another. For example, a first component may be referred to as a second component and vice versa without departing from the scope of the embodiment. Accordingly, it will be understood that although the terms first, second, etc. may be used herein to describe various elements, these elements should not be limited by these terms. These terms are generally only used to distinguish one element from another.

The singular expressions comprise plural expressions unless the context clearly dictates otherwise. The terms ‘part’ or ‘module’ used in embodiments may mean a software or hardware element such as an FPGA or ASIC, and the ‘part’ or ‘module’ may perform predetermined roles. However, ‘part’ or ‘module’ is not limited to the software or hardware.

The “part” or “module” may be provided in an addressable storage medium and configured to cause one or more processors to execute. Accordingly, as one example, a “part” or “module” may comprise elements such as software elements, object-oriented software elements, class elements and task elements, as well as processes, functions, attributes, procedures, subroutines, segments of program code, drivers, firmware, microcode, circuitry, data, database, data structures, tables, arrays and variables. The functions provided within the elements and “parts” or “modules” may be combined and “sub-part” or “modules” or further separated into additional elements and “parts” or “modules.”

The steps of a method or algorithm described in connection with some embodiments of the present disclosure may be directly implemented in hardware, in a software module executed by a processor, or in a combination of the two. The software module may be provided in RAM memory, flash memory, ROM memory, EPROM memory, EEPROM memory, registers, a hard disk, a removable disk, a CD-ROM, or any other form of storage medium known in the art. An exemplary storage medium may be coupled to a processor such that the processor may read information from the storage medium and write information to the storage medium.

Alternatively, a recording medium may be integral with the processor. The processor and the recording medium may be provided in an application specific integrated circuit ASIC. The ASIC may be provided in a user terminal. Hereinafter, referring to the accompanying drawings, embodiments of the present disclosure will be described in detail, to be understood by those skilled in the art to which the present disclosure pertains. However, the present disclosure may be embodied in various modified examples, and is not limited to embodiments described herein. Accordingly, it is an object of the present disclosure to address the aforementioned disadvantages of the prior art, and embodiments of the present disclosure may provide high voltage power devices that are robust to an ESD events.

In addition, embodiments of the present disclosure may provide high voltage integrated circuits that are ESD robust by adding SCRs.

Aspects of the present disclosure are not limited to the above aspects, and other aspects and advantages not mentioned above will be clearly understood from the following description, and even more clearly from the embodiments disclosed herein.

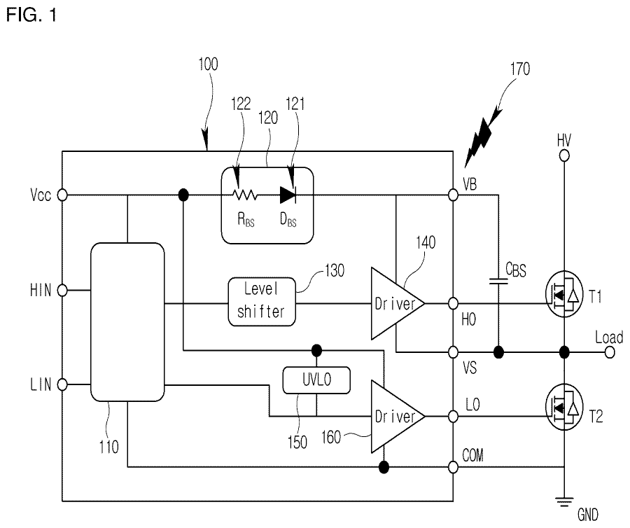

FIG. 1 illustrates a schematic of a high voltage integrated circuit according to one embodiment.

Referring to FIG. 1, a high voltage integrated circuit (HVIC) 100 may comprise a control unit 110 configured to provide a gate control signal to the gate of an external switching element T1 and T2, a bootstrap circuit 120, a level shifter 130, a high side gate driver (i.e., HS Driver) 140, an Under Voltage LOckout (i.e., UVLO) 150, and a low side gate driver (i.e., LS Driver) 160. The control unit 110 may provide control input to the high side gate driver 140 and the low side gate driver 160 for generating a gate control signal of the switching element T1 and T2 based on the external control signal.

The bootstrap circuit 120 may comprise a bootstrap diode 121 and a bootstrap resistor 122. The bootstrap resistor 122 may not be provided. The bootstrap diode 121 may use a PN diode or Schottky diode. The bootstrap circuit 120 may power the gate control signal to drive the first switching element T1 with an externally connected bootstrap capacitor CBS.

The level shifter 130 may provide a high side gate control signal to a high side gate buffer. The low side level shifter (not shown) may also be disposed in the HVIC 100 which provides a low side gate control signal to a low side gate buffer. The level shifter 130 may comprise a laterally diffused metal oxide semiconductor (LDMOS), an extended drain metal oxide semiconductor (EDMOS) or a diffused metal oxide semiconductor (DMOS).

The element formed in the level shifter 130 may have a structure that can withstand high voltage, because it has one side connected to a high voltage region. The high side gate driver 140 may generate a signal for controlling the first switching element T1, and the low side gate driver 160 may generate a signal for controlling the second switching element T2. The UVLO 150 may have a function of detecting when the low side gate driver 160 is too small to operate and stopping its operation. The UVLO 150 may perform the low side detection and shutdown function not only for the voltage associated with the low side gate driver 160 shown in FIG. 1, but also for the input voltage or the voltage associated with the high side gate driver 140.

The first switching element T1 and the second switching element T2 may be an N-type metal oxide semiconductor field effect transistor (MOSFET) or an insulated gate bipolar transistor (IGBT). The first switching element T1 may be provided between a high voltage HV and load, and a source may be electrically connected to the high voltage HV and a drain may be electrically connected to the load.

A gate of the first switching element T1 may be electrically connected to a high side output terminal HO of the HVIC 100, so that the first switching element T1 can be turned on/off by the voltage output from the high side output terminal HO. The first switching element T1 may output high voltage HV to the load when it is turned on. The second switching element T2 may be provided between a ground voltage GND and the load, so that the source can be electrically connected to the load and a drain may be electrically connected to the ground voltage GND.

A gate of the second switching element T2 may be electrically connected to a low side output terminal LO of the HVIC 100, so that the second switching element T2 can be turned on/off by the voltage output from the low side output terminal LO. The second switching element T2 may output ground voltage to the output load when it is turned on. A drain of the first switching element T1 and a source of the second switching element T2 may be electrically connected together to the load.

Referring to FIG. 1, the HVIC 100 for exchanging signals with the outside and receiving power for operation may comprise a voltage input terminal Vcc, a high side control input terminal HIN, a low side control input terminal LIN, a ground terminal COM, a high voltage terminal VB, a high voltage return voltage terminal VS, a high side output terminal HO, and a low side output terminal LO.

The HVIC 100 may supply the power required for driving through the voltage input terminal Vcc, and may be electrically connected to an external ground voltage GND through the ground terminal COM to form a ground isolated from the outside. The high voltage circuit 100 may output a high side control signal via the high side output terminal HO, and the high side control signal may control the operation of the first switching element T1 in response to a logic signal input via the high side control input terminal HIN.

The high side output terminal HO may be electrically connected to a gate of the first switching element T1 and configured to control the switching of the first switching element T1. The HVIC 100 may output a low side control signal via a low side output terminal LO, and the low side control signal may control the operation of the second switching element T2 in response to a logical signal input through a low side control input terminal LIN. The low side output terminal LO may be electrically connected to a gate of the second switching element T2 and configured to control the switching of the second switching element T2.

The first switching element T1 and the second switching element T2 may be controlled to not be switched on at the same time. For example, while the first switching element T1 is controlled to be switched on, the second switching element T2 may be controlled to be switched off. Alternatively, while the first switching element T1 is controlled to be switched off, the second switching element T2 may be controlled to be switched on.

A bootstrap capacitor CBS may be electrically connected between the high voltage terminal VB and the high voltage returned voltage terminal VS, and the high voltage return voltage terminal VS may be electrically connected to load, the drain of the first switching element T1 and the source of the second switching element T2.

The bootstrap diode 121 disposed within the HVIC 100 and the external bootstrap capacitor CBS may be serially connected to each other. The anode of the bootstrap diode 121 may be electrically connected to a driving power supplied through the voltage input terminal Vcc via a bootstrap resistor 122. One end (e.g., cathode) of the bootstrap capacitor CBS may be electrically connected to the load, the high voltage return voltage terminal VS, the drain of the first switching element T1, and the source of the second switching element T2.

A cathode of the bootstrap diode 121 and the other end of the bootstrap capacitor CBS may be electrically connected to each other, so that driving power can be supplied to the high side gate driver 140 at the connected point.

When the second switching element T2 is turned on and the first switching element T1 is turned off, the voltage applied to one end of the bootstrap capacitor CBS becomes ground voltage GND so that a forward voltage can be applied to the bootstrap diode 121 and a forward bias current can flow.

Due to the forward bias current, a voltage of a value obtained by subtracting the voltage applied to the bootstrap resistor 122 and the threshold voltage of the bootstrap diode 121 from the driving voltage input through the voltage input terminal Vcc may be applied to the high voltage terminal VB by the forward bias current. The bootstrap capacitor CBS may be charged by the voltage output from the high voltage terminal VB.

When the first switching element T1 is turned on and the second switching element T2 is turned off, the voltage applied to one end of the bootstrap capacitor CBS may become a higher voltage HV greater than the driving voltage Vcc and a reverse voltage may be applied to the bootstrap diode 121, so the flow of current may be blocked by the bootstrap diode. At this time, a value obtained by adding the voltage charged in the bootstrap capacitor CBS to the high voltage HV applied to one end of the bootstrap capacitor CBS may be applied to the high voltage terminal VB.

As this voltage is output to the high side output terminal HO by driving the high side gate driver 140, the voltage between the source and gate of the first switching element T1 may become a charging voltage for the bootstrap capacitor CBS. Since this charging voltage is greater than the threshold voltage of the first switching element T1, the first switching element T1 may be stably driven.

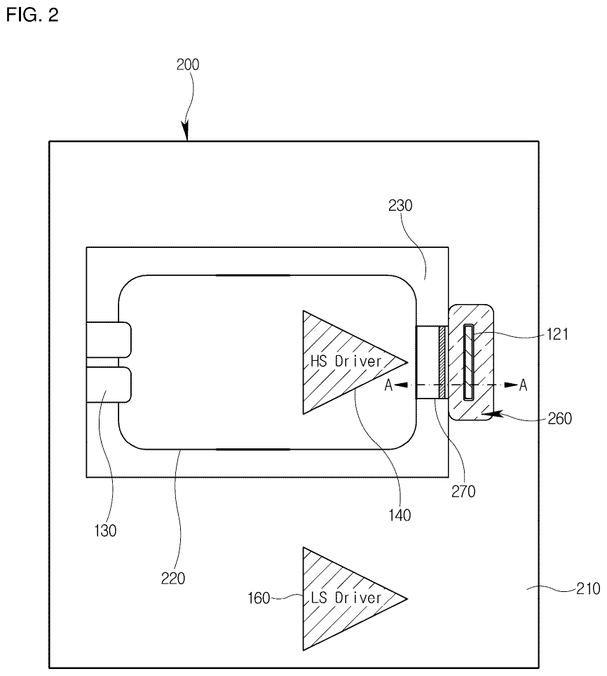

FIG. 2 illustrates a plan view of a high voltage power device having an ESD self-protection structure, according to one embodiment of the present disclosure.

Referring to FIG. 2, the high voltage power device 200 may comprise the bootstrap diode 121, the level shifter 130, the HS driver 140, the LS driver 160, a low voltage region 210, a high voltage region 220, a junction isolation region 230, a guard ring structure 260, and LDMOS or JFET structure 270.

The bootstrap diode 121 may be disposed adjacent to the junction isolation region 230, and may include a PN diode or a Schottky diode. In the present disclosure, the bootstrap diode 121 comprising a Schottky diode is illustrated. The forward current from the bootstrap diode 121 may charge the bootstrap capacitor CBS to a sufficient voltage.

Accordingly, by applying the sufficient voltage to the gate of the first switching element T1, switching may occur smoothly. Additional bootstrap diodes may be disposed in the high voltage power device 200.

The level shifter 130 may provide a high side gate control signal to a high side gate buffer in the high voltage power device 200. The low side level shifter (not shown) may also be disposed in the high voltage power device 200 to provide a low side gate control signal to the low side gate buffer.

A junction isolation region 230 may be provided to electrically isolate the low voltage region 210 from the high voltage region 220. The low voltage region 210 may comprise a low side semiconductor device operating at a low voltage, such as a low side gate driver 160. The high voltage region 220 may comprise a high side semiconductor device operating at a high voltage, such as the high side gate driver 140.

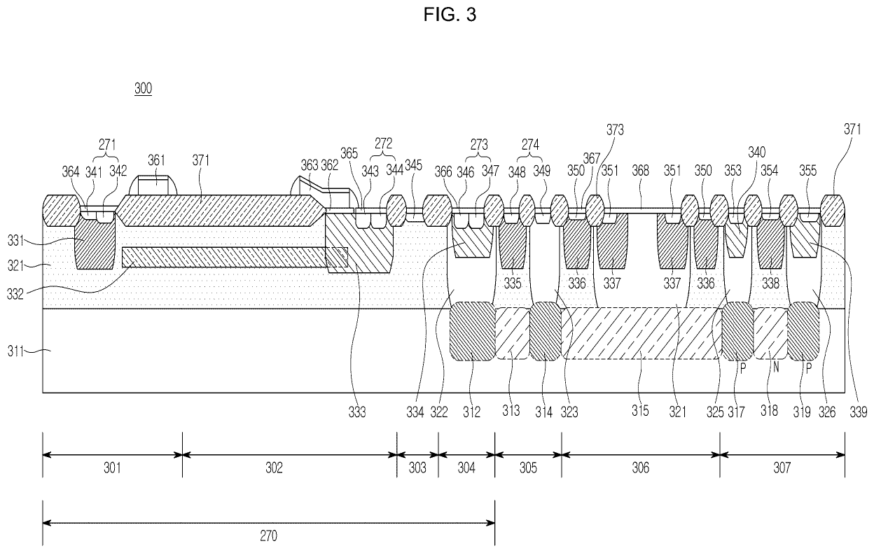

Here, the low voltage range may be below 30V and the high voltage range may be up to 1200V. A junction field effect transistor (JFET) or a laterally diffused metal-oxide semiconductor (LDMOS) type device may be arranged in the junction isolation region 230. The guard ring structure 260 may be configured to surround the bootstrap diode 121. The guard ring structure 260 may comprise a PNP guard ring or NP guard ring. The LDMOS or JFET structure 270 may comprise an SCR device as described in detail in FIG. 3.

FIG. 3 illustrates a cross-sectional view of a high voltage power device comprising a Schottky diode with ESD self-protection structure according to one embodiment of the present disclosure. FIG. 3 illustrates a cross-sectional view of the A-A section in FIG. 2.

Referring to FIG. 3, the high voltage power device 300 comprising a Schottky diode with ESD self-protection structure may comprise a SCR region 270, a first guard ring 305, a PN diode 306 and a second guard ring 307. Here, the SCR region 270 may comprise a drain region 301, a gate region 302, a source region 303 and a P-type isolation region 304.

The Schottky diode 306 may be configured to supply a forward current to the drain region 301 through the source region 303. The first guard ring 305 and the second guard ring 307 may surround the Schottky diode 306, and may be configured to block leakage current that may flow into the substrate 311.

To discharge the ESD current to the ground node, the P-type isolation region 304 or the first guard ring 305 may be disposed between the source region 303 and the PN diode 306. The first guard ring 305 and the second guard ring 307 may be referred to as an NP guard ring and a PNP guard ring.

The high voltage power device 300 may comprise a first SCR (i.e., silicon controlled rectifier) 271 formed in a drain region 301, a second SCR 272 formed in a gate region 302, a third SCR 273 formed in a P-type isolation region 304, and a fourth SCR 274 in a first guard ring 305.

The drain region 301 may comprise a P-type semiconductor substrate (P-sub) 311, an DNW (high voltage deep N-type well region or N-type semiconductor region) 321 formed on the P-sub 311, an N-type well region 331 formed in the DNW 321, a first N-type high concentration doped (N+) region 341 and a first P-type high concentration doped (P+) region 342, which may be formed in contact with each other within the N-type well region 331. Here, the first N+ region 341 and the first P+ region 342 may correspond to the first SCR 271.

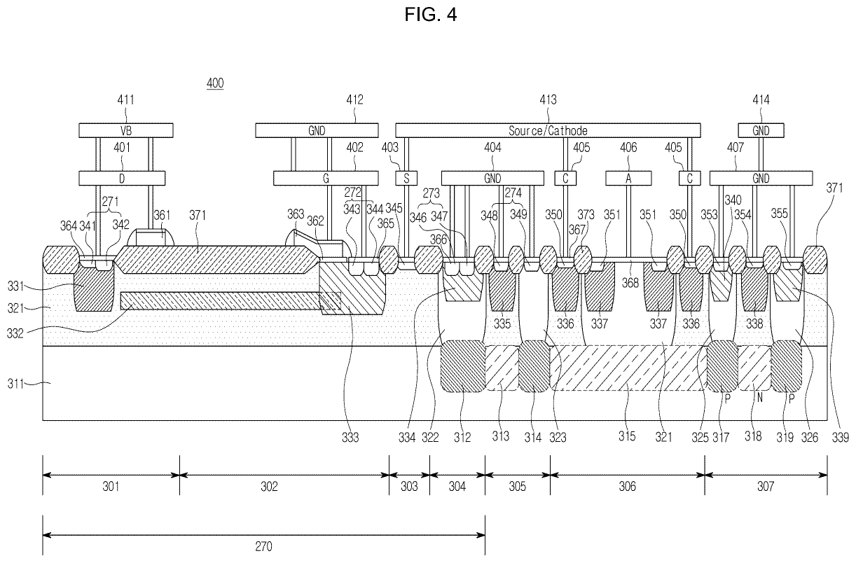

Here, the first SCR 271 may be electrically connected to a high voltage terminal 411 (see FIG. 4). In addition, the drain region 301 may further comprise a Poly-Si field plate 361 formed on a field oxide layer (FOX) 371, and a drain silicide layer 364 formed on the first SCR 271. The drain silicide layer 364 may electrically connect to both the first N+ region 341 and the first P+ region 342. The drain silicide layer 364 may comprise a material such as cobalt silicide, nickel silicide and titanium silicide.

The gate region 302 has a very long horizontal length and thus provides a surface electric field relaxation effect, so it can be called a reduced surface electric field (RESURF) region. The gate region 302 may comprise a gate insulating layer 362 formed on the P-sub 311; a gate electrode 363 formed on the gate insulating layer 362 as well as the FOX 371; a P-type body region (PBODY) 333 formed to overlap the gate electrode 363; a second N+ region 343 and a second P+ region 344 in contact with each other and formed in the PBODY 333; a P-type top layer (PTOP) 332 formed between the drain NW 331 and the PBODY 333, which helps alleviate the electric field. The gate insulating layer 362 may comprise a material such as silicon oxide, silicon oxynitride, tantalum oxide (Ta2O5), hafnium oxide (HfO2), aluminum oxide (Al2O3), etc. The gate electrode 363 may comprise a material such as Poly-Si, Cu, W, WN, TiN, etc. Here, the gate electrode 363, the PBODY 333 and the second N+ region 343 and the second P+ region 344 may each be electrically connected to a ground voltage GND (see FIG. 4).

The second N+ region 343 and the second P+ region 344 formed in contact with each other in the PBODY 333 may correspond to the second SCR 272. The gate region 302 may further comprise a body silicide layer 365 formed on the second N+ region 343 and the second P+ region 344. The body silicide layer 365 may comprise a material such as cobalt silicide, nickel silicide and titanium silicide.

The source region 303 may comprise a N+ source region 345 formed in the DNW 321. The N+ source region 345 may be disposed between the PBODY 333 overlapping the gate electrode 363, and the P-type isolation region 304. The source region 303 may be disposed between the second SCR 272 and the third SCR 273. In addition, the source region 303 may be arranged between the SCR region 270 and the P-type isolation region 304.

The third SCR 273 may be formed in the P-type isolation region (P-ISO) 304, and the fourth SCR 274 may be formed in the first guard ring 305. The P-type isolation region 304 comprises a P-type isolation buried layer (ISO PBL) 312, a first P-type isolation deep well region (ISO DPW) 322, a first P-type isolation well region (ISO PW) 334, a third N+ region 346 and a third P+ region 347.

Here, the third N+ region 346 and the third P+ region 347 may be corresponding to the third SCR 273. The P-ISO 304 may further comprise a silicide layer 366 formed on the third N+ region 346 and the third P+ region 347. The SCR region 270 may comprise the first SCR 271, the second SCR 272, and the third SCR 273.

The high voltage power device 300 may comprise a first guard ring 305 and a second guard ring 307. The first guard ring 305 and the second guard ring 307 may be formed to surround the Schottky diode 306 to reduce leakage current that may occur in the vicinity of the Schottky diode 306. The first guard ring 305 may be formed as an NP guard ring, and the second guard ring 307 may be formed as a PNP guard ring.

Accordingly, the first guard ring 305 may be referred to as the NP guard ring and the second guard ring 307 may be referred to as the PNP guard ring.

First, the first guard ring 305 may comprise a first NBL 313 and an N-type well region (NW) 335 formed on the P-sub 311; a fourth N+ region 348 formed in the NW 335; a first PBL 314 and a first P-type deep well region (DPW) 323 formed on the P-sub 311; and a fourth P+ region 349 formed in the first DPW 323.

The fourth N+ region 348 and the fourth P+ region 349, which are formed separately by the FOX 371 may correspond to the fourth SCR 274.

The ISO PBL 312, the first NBL 313 and the first PBL 314 may be formed parallel to each other. The ISO PBL 312 may be formed under the third SCR 273. The first NBL 313 and the first PBL 314 may be formed under the fourth SCR 274.

The third SCR 273 and the fourth SCR 274 may be electrically connected to each other through a contact plug and metal wiring, so that both can be electrically connected to ground voltage GND (see FIG. 4).

The second guard ring 307 may comprise a PNP guard ring. The PNP guard ring may comprise a first P-type guard ring (P), an N-type guard ring (N) and a second P-type guard ring (P). The first P-type guard ring (P) may comprise a second PBL 317 formed on the P-sub 311; a second DPW 325; a PW 340; and a fifth P+ region 353. The N-type guard ring (N) may comprise a second NBL 318 formed on the P-sub 311; an NW 338; and a fifth N+ region 354. The second P-type guard ring (P) may comprise a third PBL 319 formed on the P-sub 311; a third DPW 326; a PW 339; and a sixth P+ region 355. The fifth P+ region 353, the fifth N+ region 354 and the sixth P+ region 355 may be separated from each other by the FOX 371.

The Schottky diode 306 may comprise a third NBL 315, an DNW 321 formed on the third NBL 315; an N-type cathode well region 336 and an N+ cathode region 350 formed in the DNW 321; a P-type anode well region 337 and a P+ anode region 351. The N-type cathode well region 336 may be formed on each of both sides spaced apart from each other.

The P-type anode well region 337 may be formed on each of both sides spaced apart from each other, and surround a bottom corner region of the FOX 373. Accordingly, the P-type anode well region 337 may increase a breakdown voltage of the Schottky barrier diode. This is because the bottom corner region of the FOX 373 may be a region where stress is concentrated, where a high electric field is formed and where breakdown easily occurs.

Accordingly, when the P-type anode well region 337 is formed to surround the bottom corner region of the FOX 373, there may be an effect of reducing the electric field and thus the breakdown voltage can be improved. Here, the depth of the P-type canoed well region 337 may be greater than the depth of the FOX 373.

The Schottky diode 306 may further comprise a first silicide layer 367 and a second silicide layer 368. The first silicide layer 367 may be provided for cathode contact, and may be disposed above the N-type cathode well region 336 and the N+ cathode region 350. The second silicide layer 368 for anode contact may be formed in contact with the DNW 321, the P-type anode well region 337, and the P+ anode region 351. The first silicide layer 367 and the second silicide layer 368 may comprise materials such as cobalt silicide, nickel silicide and titanium silicide.

FIG. 4 illustrates a cross-sectional view of a high voltage power device comprising a metal interconnection according to one embodiment of the present disclosure.

Referring to FIG. 4, a drain region 301 may comprise a first SCR 271 in the high voltage power device 400. The first SCR 271 may comprise the first N+ and P+ regions 341 and 342 which may be electrically connected to a drain electrode 401. A Poly-Si field plate 361 formed on a FOX 371 may also be electrically connected to a drain electrode 401. The drain electrode 401 may be electrically connected to a high voltage terminal 411.

Accordingly, the Poly-Si field plate 361 and the first N+ and P+ region 341 and 342 may be electrically connected to the high voltage terminal 411. A bootstrap capacitor CBS may be charged by the voltage output from the high voltage terminal 411. A high voltage of 600V or more may be applied to the high voltage terminal 411.

The PBODY 333, second N+ region 343, the second P+ region 344 and the gate electrode 363 may be electrically connected to a first ground voltage 412 through a gate metal 402 in the gate region 302.

A P-type isolation region 304 may comprise a third SCR 273. A first guard ring 305 may comprise a fourth SCR 274. Both the third SCR 273 and the fourth SCR 274 may be electrically connected to a second ground voltage 404. Therefore, the second SCR 272, the third SCR 273 and the fourth SCR 274 may be electrically connected to the ground voltage GND.

An N+ source region 345 may be formed between the second SCR 272 and the third SCR 273. The N+ source region 345 may be electrically connected to a source electrode 403 in the source region 303. The source electrode 403 may be electrically connected to a cathode electrode 405 through the source/cathode electrode 413.

When a high voltage is applied to the first SCR 271 in the off-state, a pinch-off phenomenon may occur between the gate region 302 and the P-type isolation region 304. In other words, a pinch-off may occur between the PBODY 333 and the DPW 322.

When a high voltage of about 600V or more is applied to the drain electrode 401 in the off-state, the current from the drain electrode 401 to the source electrode 403 may be blocked by the pinch-off phenomenon. The pinch-off must occur to protect the Schottky diode 306 from high voltages above 600V in the off-state.

The first silicide layer 367 formed on the N+ cathode region 350 may be electrically connected to the cathode electrode 405 in the Schottky diode 306. The second silicide layer 368 formed on the P+ anode region 351 may be electrically connected to an anode electrode 406 where a VCC power source is supplied.

The second guard ring 307 may comprise the PNP guard ring comprising the first P-type guard ring (P), the N-type guard ring (N) and the second P-type guard ring (P). The first P-type guard ring (P) may comprise a second PBL 317 formed on the P-sub 311; a second DPW 325; a PW 340; and a fifth P+ region 353. The N-type guard ring (N) may comprise a second NBL 318 formed on the P-sub 311; an NW 338; and a fifth N+ region 354.

The second P-type guard ring (P) may comprise a third PBL 319 formed on the P-sub 311; a third DPW 326; a PW 339; and a sixth P+ region 355. The fifth P+ region 353, the fifth N+ region 354 and the sixth P+ region 355 may be electrically connected to the ground electrodes (GND) 407 and 414. Silicide layer may also be formed on each of the fifth P+ region 353, the fifth N+ region 354 and the sixth P+ region 355.

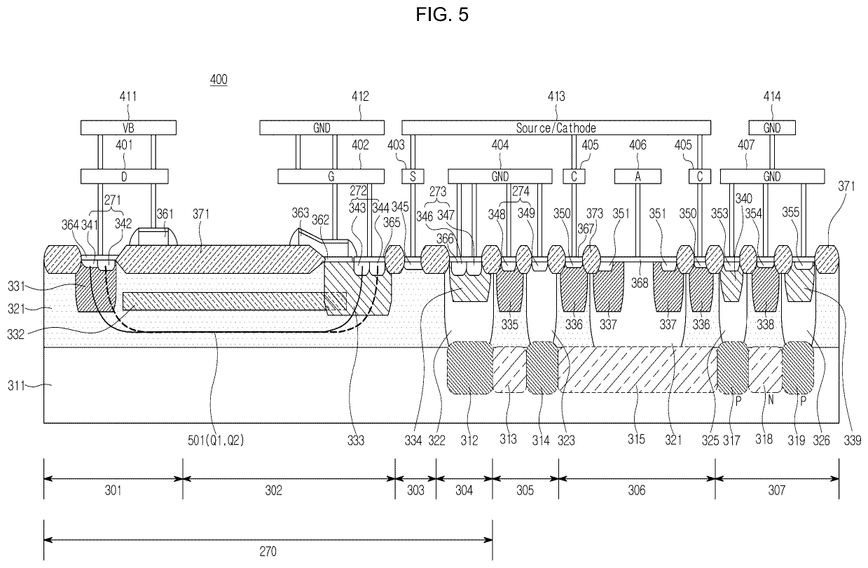

FIGS. 5 to 7 illustrate a cross-sectional view showing an ESD current discharge path according to one embodiment of the present disclosure.

Referring to FIG. 5, the first SCR 271 and the second SCR 272 with the DNW 321 may be combined to form a first ESD discharge path 501 when an ESD surge 170 may enter to the drain electrode 401 in the high voltage power device 400. The first N+ region 341, the DNW 321 and the second N+ region 343 form a parasitic NPN transistor (Q1). The first P+ region 342, the DNW 321 and the second P+ region 344 form a parasitic PNP transistor (Q2).

The parasitic NPN and PNP transistors may provide the first ESD current discharge path 501. Thus, the first ESD current discharge path 501 may start from the first N+ or P+ region 341 or 342 of the first SCR 271 through the DNW 321 into the second N+ or P+ region 343 or 344 of the second SCR 272.

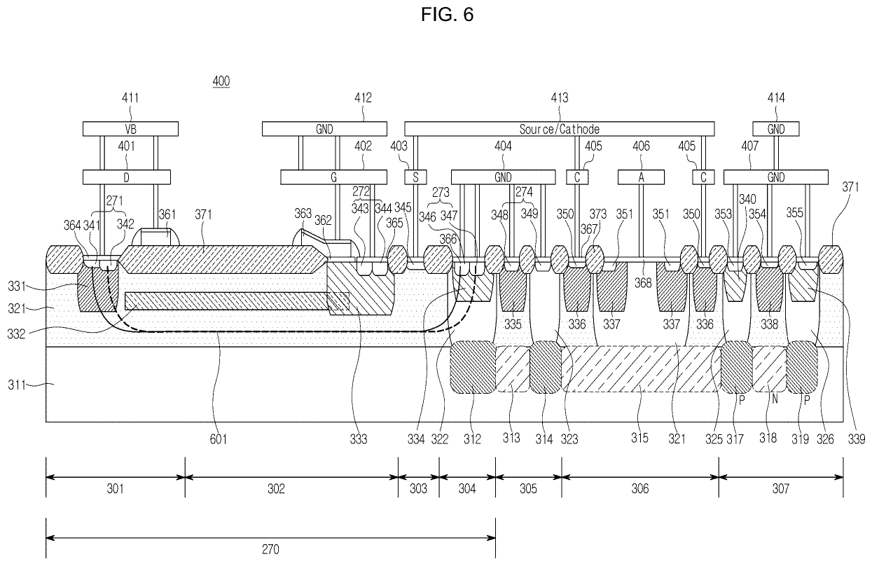

Referring to FIG. 6, the first SCR 271 and the third SCR 273 with the DNW 321 may be combined to form a second ESD discharge path 601 when an ESD surge 170 may enter to the drain electrode 401 in the high voltage power device 400. The first N+ region 341, the DNW 321 and the third N+ region 346 form a second parasitic NPN transistor.

The first P+ region 342, the DNW 321 and the third P+ region 347 form a second parasitic PNP transistor. The second parasitic NPN and PNP transistors may provide the second ESD current discharge path 601. Thus, the second ESD current discharge path 601 may start from the first N+ or P+ region 341 or 342 of the first SCR 271 through the DNW 321 into the third N+ or P+ region 346 or 347 of the third SCR 273.

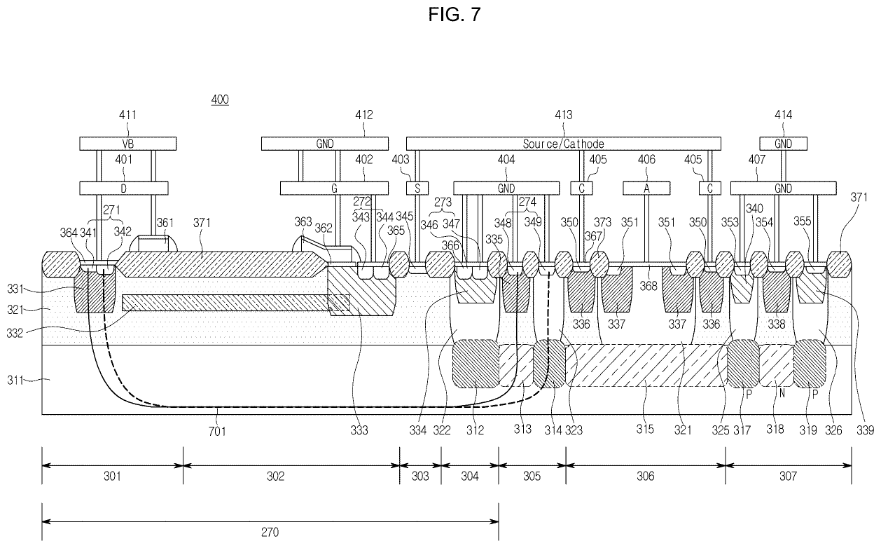

Referring to FIG. 7, the first SCR 271 and the fourth SCR 274 with the P-sub 311 may be combined to form a third ESD discharge path 701 when an ESD surge 170 may enter to the drain electrode 401 in the high voltage power device 400. The first N+ region 341, the P-sub 311 and the fourth N+ region 348 form a parasitic NPN transistor. The first P+ region 342, the P-sub 311 and the fourth P+ region 349 form a parasitic PNP transistor.

The parasitic NPN and PNP transistors may provide the third ESD current discharge path 701. Thus, the third ESD current discharge path 701 may start from the first N+ or P+ region 341 or 342 of the first SCR 271 through the P-sub 311 into the fourth N+ or P+ region 348 or 349 of the fourth SCR 274.

Since ESD current may be discharged through the first SCR 271, the second SCR 272, the third SCR 273 and the fourth SCR 274, the high voltage power device 400 may have high ESD immunity.

Although the present embodiment has been described with reference to the exemplified drawings, it is to be understood that the present embodiment is not limited to the embodiments and drawings disclosed in this specification, and those skilled in the art will appreciate that various modifications are possible without departing from the scope and spirit of the present embodiment. Furthermore, although the operational effects of the configurations of the present disclosure have not been explicitly described, it should be appreciated that predictable effects may be recognized by the configurations of the present disclosure.

What is claimed is:

1. A semiconductor device, comprising:
a high voltage region formed on a semiconductor substrate;
a junction isolation region surrounding the high voltage region;
a Schottky diode configured to supply a forward current to the high voltage region;
a silicon controlled rectifier (SCR) region formed between the Schottky diode and the high voltage region;
a drain region, a gate region and a source region formed in the SCR region;
a P-type isolation region formed between the Schottky diode and the source region;
a first SCR comprising a first N+ region and a first P+ region in contact with each other and formed in the drain region;
a second SCR comprising a second N+ region and a second P+ region in contact with each other and formed in the gate region; and
a third SCR comprising a third N+ region and a third P+ region in contact with each other and formed in the P-type isolation region.

2. The semiconductor device of claim 1, further comprising:
an NP guard ring and a PNP guard ring that surround the Schottky diode,
wherein the NP guard ring comprises:
a fourth N+ region formed on a first N-type buried layer (NBL); and
a fourth P+ region formed on a first P-type buried layer (PBL),
wherein the PNP guard ring comprises:
a fifth P+ region formed on a second PBL;
a fifth N+ region formed on a second NBL; and
a sixth P+ region formed on a third PBL, and
wherein a fourth SCR comprises the fourth N+ region and the fourth P+ region.

3. The semiconductor device of claim 1,
wherein the drain region comprises:
a drain N-type well region (NW) surrounding the first SCR; and
a field plate electrically connected to the first SCR and formed on a field oxide layer,
wherein the gate region comprises:
an N-type deep well region (DNW) formed on the semiconductor substrate;
a P-type top layer (PTOP) formed on the DNW;
a P-type body region (PBODY) connected to the PTOP;
the second SCR formed on the PBODY; and
a gate electrode formed to overlap the PBODY, and
wherein the source region comprises an N+ source region formed on the DNW.

4. The semiconductor device of claim 1,
wherein the P-type isolation region comprises a P-type isolation buried layer (PBL) formed under the third SCR.

5. The semiconductor device of claim 2,
wherein the first SCR is connected to a high voltage terminal, and
wherein the second SCR, the third SCR, and the fourth SCR are connected to a ground voltage.

6. The semiconductor device of claim 1,
wherein the Schottky diode comprises:
a third NBL formed in the semiconductor substrate;
an N-type deep well region (DNW) formed on the third NBL;
an N-type cathode well region formed on the DNW;
a P-type anode well region formed separately from the N-type cathode well region by a separator;
a first silicide formed on the N-type cathode well region;
a second silicide formed on the P-type anode well region;
a cathode electrode formed on the first silicide; and
an anode electrode formed on the second silicide, and
wherein the cathode electrode is electrically connected to a source electrode of the source region.

7. A semiconductor device, comprising:
a high voltage region formed on a semiconductor substrate;
a junction isolation region surrounding the high voltage region;
a Schottky diode configured to supply a forward current to the high voltage region;
a silicon controlled rectifier (SCR) region formed between the Schottky diode and the high voltage region; and
a drain region, a gate region and a source region formed in the SCR region,
wherein the SCR region comprises:
a first SCR comprising a first N+ region and a first P+ region in contact with each other and formed on a drain N-type well region (NW);
a second SCR comprising a second N+ region and a second P+ region in contact with each other and formed on a P-type body region (PBODY); and
a third SCR comprising a third N+ region and a third P+ region in contact with each other and formed on a P-type isolation region.

8. The semiconductor device of claim 7, further comprising:
an NP guard ring and a PNP guard ring that surround the Schottky diode,
wherein the NP guard ring comprises:
a fourth N+ region formed on a first N-type buried layer (NBL); and
a fourth P+ region formed on a first P-type buried layer (PBL),
wherein the PNP guard ring comprises:
a fifth P+ region formed on the second PBL;
a fifth N+ region formed on a second NBL; and
a sixth P+ region formed on a third PBL, and
wherein a fourth SCR comprises the fourth N+ region and the fourth P+ region.

9. The semiconductor device of claim 7,
wherein the drain region comprising the first SCR further comprises a field plate electrically connected to the first SCR and formed on a field oxide layer, and
wherein the gate region comprising the second SCR further comprises:
a P-type top layer (PTOP) connected to the PBODY; and
a gate electrode formed on the PBODY.

10. The semiconductor device of claim 7,
wherein the P-type isolation region comprising the third SCR further comprises a P-type isolation buried layer formed under the third SCR.

11. The semiconductor device of claim 8,
wherein the first SCR is connected to a high voltage terminal, and
wherein the second SCR, the third SCR, and the fourth SCR are connected to a ground voltage.

12. The semiconductor device of claim 7,
wherein the Schottky diode comprises:
a third NBL formed in the semiconductor substrate;
an N-type deep well region (DNW) formed on the third NBL;
an N-type cathode well region formed on the DNW;
a P-type anode well region formed separately from the N-type cathode well region by a separator;
a first silicide formed on the N-type cathode well region;
a second silicide formed on the P-type anode well region;
a cathode electrode formed on the first silicide; and
an anode electrode formed on the second silicide.

13. The semiconductor device of claim 12,
wherein the source region is formed between the second SCR and the third SCR,
wherein the source region comprises:
an N+ source region formed on the DNW; and
a source electrode connected to the source region, and
wherein the source electrode is electrically connected to the cathode electrode.
